(19) United States
(12) Patent Application Publication
(10) Pub. No.: US 2024/0258395 A1
(43) Pub. Date: Aug. 1, 2024

(54) OHMIC CONTACT STRUCTURE AND MANUFACTURING METHOD THEREFOR, AND APPLICATION THEREOF

(71) Applicant: XIAMEN SAN'AN INTEGRATED CIRCUIT CO., LTD., Xiamen (CN)

(72) Inventors: Wangping WANG, Xiamen (CN); Jieli TAN, Xiamen (CN); Jiangshi XU, Xiamen (CN)

(21) Appl. No.: 18/629,980

(22) Filed: Apr. 9, 2024

Related U.S. Application Data
(63) Continuation of application No. PCT/CN2023/130871, filed on Nov. 10, 2023.

(30) Foreign Application Priority Data
Dec. 27, 2022 (CN) 2022116911945

(51) Int. Cl. H01L 29/45; H01L 21/285

(52) U.S. Cl. CPC H01L 29/452; H01L 21/28575

(57) ABSTRACT

Provided are an ohmic contact structure, a manufacturing method therefor, an HEMT device and an application thereof. The manufacturing method for an ohmic contact structure includes: providing an epitaxial layer for manufacturing an ohmic contact metal electrode; sequentially evaporating an adhesive layer and a covering layer at a position of the epitaxial layer corresponding to the ohmic contact metal electrode in a vacuum environment; exposing the epitaxial layer evaporated with the adhesive layer and the covering layer to the atmosphere to oxidize a metal material of a surface of the covering layer to thereby form a diffusion-blocking layer; sequentially evaporating a connecting layer and a protective layer on the diffusion-blocking layer in the vacuum environment; and annealing the epitaxial layer formed with the connecting layer and the protective layer at an environment temperature of 500° C.-600° C. to thereby form the ohmic contact structure.

### TECHNICAL FIELD

The present disclosure relates to the technical field of semiconductors, and particularly to an ohmic contact structure and a manufacturing method therefor, and a high electron mobility transistor (HEMT) device.

### BACKGROUND

Gallium nitride, as a wide bandgap (WBG) semiconductor, has the advantages of a larger bandgap, a higher breakdown field strength, and a higher electron saturation drift speed. Gallium nitride HEMT has obvious advantages in microwave high-power devices and high-voltage power electronic devices, and has become one of the current research hotspots. An ohmic contact structure is the key technology of a gallium nitride HEMT device. A manufacturing method of the ohmic contact structure and a resistance of the ohmic contact structure have a direct impact on the performance of the gallium nitride HEMT device. Poor ohmic contact structure will not only reduce a transconductance and an output power of the gallium nitride HEMT device, but also causes reliability problems.

In the related art, there are two methods for manufacturing the ohmic contact structure of the gallium nitride HEMT device. The first method of the two methods is to adopt a multilayer metal structure of titanium (Ti)/aluminum (Al)/nickel (Ni)/gold (Au) and conduct rapid annealing at a higher temperature (750° C.-900° C.) to manufacture a high-temperature ohmic contact structure. The second method of the two methods is to adopt a gold-free structure such as Ti/Al/titanium nitride (TiN) and Ti/Al/tungsten (W) and anneal at a lower temperature (500° C.-600° C.) to manufacture a low-temperature ohmic contact structure. For the first method, a lower contact resistance can be obtained by a high-temperature annealing ohmic process, however, the melting and diffusion of Al at the higher temperature makes a surface of the multilayer metal structure of Ti/Al/Ni/Au, that is, a surface of an electrode becomes rough and uneven, which affects the lithography and overlay for a subsequent process; also, metal spikes are easily formed on an edge of the electrode, which makes a source electrode and a gate electrode short-circuited, thereby causing reliability problems. The low-temperature ohmic contact structure manufactured by the second method has a smooth surface, but a feasible metal for a protective layer cannot be a gold material, i.e., Au, which is easy to diffuse under low-temperature annealing to form a metal-semiconductor contact, and the protective layer is generally a metal dielectric layer including titanium nitride, silicon nitride, tungsten and alumina. For an existing low-temperature ohmic process, on the one hand, a corresponding protective layer can only be manufactured by a sputtering process, but cannot be manufactured by an electron beam evaporation device, which requires sputtering equipment, thereby increasing the cost of production equipment; on the other hand, the sputtering process will make it difficult to perform photoresist stripping operation on thick metal, while a thinner protective layer is easy to be etched and perforated in a subsequent process, which reduces process yield and is prone to device failure. The existing low-temperature ohmic process generally adopts TiN, and a resistivity of TiN is higher than that of Au, therefore, the low-temperature ohmic contact structure has a higher contact resistance.

### SUMMARY

An objective of the present disclosure is to provide an ohmic contact structure of an HEMT device and a manufacturing method therefor, which can manufacture the ohmic contact structure with a smoother surface and a thicker film layer at a lower annealing temperature.

In one aspect, an embodiment of the disclosure provides a manufacturing method for an ohmic contact structure, which includes: providing an epitaxial layer for manufacturing an ohmic contact metal electrode; sequentially evaporating an adhesive layer and a covering layer at a position of the epitaxial layer corresponding to the ohmic contact metal electrode in a vacuum environment; exposing the epitaxial layer evaporated with the adhesive layer and the covering layer to the atmosphere to oxidize a metal material of a surface of the covering layer to thereby form a diffusion-blocking layer; sequentially evaporating a connecting layer and a protective layer on the diffusion-blocking layer in the vacuum environment; and annealing the epitaxial layer formed with the connecting layer and the protective layer at an environment temperature of 500° C.-600° C. to thereby form the ohmic contact structure.

In an embodiment, the sequentially evaporating an adhesive layer and a covering layer at a position of the epitaxial layer corresponding to the ohmic contact metal electrode in a vacuum environment includes: placing the epitaxial layer in a coating chamber of an electron beam evaporation coating machine and vacuumizing the coating chamber; evaporating titanium metal at the position of the epitaxial layer corresponding to the ohmic contact metal electrode to form the adhesive layer; and evaporating aluminum metal at the position of the epitaxial layer corresponding to the ohmic contact metal electrode to form the covering layer, wherein the covering layer covers the adhesive layer.

In an embodiment, the covering layer is made of aluminum metal; and the exposing the epitaxial layer evaporated with the adhesive layer and the covering layer to the atmosphere to oxidize a metal material of a surface of the covering layer to thereby form a diffusion-blocking layer includes: exposing the aluminum metal of the surface of the covering layer to the atmosphere, to make the aluminum metal react with oxygen in the atmosphere to form an aluminum oxide layer as the diffusion-blocking layer.

In an embodiment, the exposing the epitaxial layer evaporated with the adhesive layer and the covering layer to the atmosphere to oxidize a metal material of a surface of the covering layer to thereby form a diffusion-blocking layer includes: exposing the epitaxial layer evaporated with the adhesive layer and the covering layer to the atmosphere for a preset time to make a thickness of the diffusion-blocking layer be in a range from 1 nanometer (nm) to 10 nm.

In an embodiment, the sequentially evaporating a connecting layer and a protective layer on the diffusion-blocking layer in the vacuum environment includes: placing the epitaxial layer formed with the diffusion-blocking layer in a coating chamber of an electron beam evaporation coating machine and vacuumizing the coating chamber; evaporating nickel metal on the diffusion-blocking layer to form the connecting layer; and evaporating a gold material on the connecting layer to form the protective layer.

In another aspect, an embodiment of the present disclosure provides an ohmic contact structure, which is disposed on an epitaxial layer of an HEMT device. The ohmic contact structure acts as a source electrode and/or a drain electrode of the HEMT device. The ohmic contact structure includes an adhesive layer, a covering layer, a diffusion-blocking layer, a connecting layer and a protective layer which are sequentially disposed on the epitaxial layer in that order. The diffusion-blocking layer is an oxide of a metal material of the covering layer.

In an embodiment, the adhesive layer is a titanium layer, the covering layer is an aluminum layer, the diffusion-blocking layer is an aluminum oxide layer, the connecting layer is a nickel layer, and the protective layer includes gold.

In an embodiment, a thickness of the adhesive layer is in a range from 10 angstroms (Å) to 200 Å, the thickness of the covering layer is in a range from 50 Å to 2000 Å, a thickness of the diffusion-blocking layer is in a range from 10 Å to 100 Å, a thickness of the connecting layer is in a range from 100 Å to 500 Å, and a thickness of the protective layer is in a range from 500 Å to 2000 Å.

In an embodiment, a thickness ratio of the adhesive layer to the covering layer is in a range from 1:50 to 1:5.

The present disclosure has at least beneficial effects as follows.

The present disclosure provides a manufacturing method for an ohmic contact structure, which includes: providing an epitaxial layer for manufacturing an ohmic contact metal electrode; sequentially evaporating an adhesive layer and a covering layer at a position of the epitaxial layer corresponding to the ohmic contact metal electrode in a vacuum environment; exposing the epitaxial layer evaporated with the adhesive layer and the covering layer to the atmosphere to oxidize a metal material of a surface of the covering layer to thereby form a diffusion-blocking layer; sequentially evaporating a connecting layer and a protective layer on the diffusion-blocking layer in the vacuum environment; and annealing the epitaxial layer formed with the connecting layer and the protective layer at an environment temperature of 500° C.-600° C. to thereby form the ohmic contact structure. Firstly, since the epitaxial layer formed with the connecting layer and the protective layer is annealed at the environment temperature of 500° C.-600° C., the annealing temperature is relatively lower, so that metal in each layer of the ohmic contact structure is avoided from melting, and a surface of the ohmic contact structure is smoother. Secondly, due to the adoption of evaporation, a thicker metal film can be obtained than the adoption of sputtering, and thus a thicker ohmic contact structure is formed, which is beneficial to improving the yield of subsequent processes and reducing a resistivity of a corresponding ohmic electrode. Therefore, the present disclosure can manufacture a low-resistivity ohmic contact structure with a smoother surface and a thicker film layer in a lower temperature environment.

### BRIEF DESCRIPTION OF DRAWINGS

In order to explain technical solutions of embodiments of the present disclosure more clearly, the following accompanying drawings will be briefly introduced hereinafter. It should be understood that the following accompanying drawings merely show some embodiments of the present disclosure, and should not be regarded as limiting the scope of protection of the present disclosure. For the skilled in the art, other related drawings can be obtained according to these introduced drawings without creative work.

FIG. 1 illustrates a flowchart of a manufacturing method for an ohmic contact structure according to an embodiment of the present disclosure.

FIG. 2 illustrates a first state diagram of a manufacturing method for an ohmic contact structure according to an embodiment of the present disclosure.

FIG. 3 illustrates a second state diagram of a manufacturing method for an ohmic contact structure according to an embodiment of the present disclosure.

FIG. 4 illustrates a third state diagram of a manufacturing method for an ohmic contact structure according to an embodiment of the present disclosure.

FIG. 5 illustrates an energy dispersive spectroscopy (EDS) single-point scanning diagram of a diffusion-blocking layer according to an embodiment of the present disclosure.

FIG. 6 illustrates a first EDS mapping of a diffusion-blocking layer according to an embodiment of the present disclosure.

FIG. 7 illustrates a second EDS mapping of a diffusion-blocking layer according to an embodiment of the present disclosure.

FIG. 8 illustrates a voltage-current curve of a metal-semiconductor contact formed by low-temperature annealing of a metal structure of Ti—Al—Ni—Au.

FIG. 9 illustrates a voltage-current curve of an ohmic contact formed by low-temperature annealing of Ti—Al—AlOx-Ni—Au according to an embodiment of the present disclosure.

### REFERENCE NUMERALS

10—Ohmic contact structure; 11—Adhesive layer; 12—Covering layer; 13—Diffusion-blocking layer; 14—Connecting layer; 15—Protective layer; 20—Substrate; and 30—Epitaxial layer.

### DETAILED DESCRIPTION OF EMBODIMENTS

In order to make the objective, technical solutions and advantages of embodiments of the present disclosure more clearly, the technical solutions in the embodiments of the present disclosure will be described clearly and completely with accompanying drawings. Apparently, the described embodiments are part of embodiments of the present disclosure, but not the whole embodiments. Components of the described embodiments of the present disclosure, which are generally described and illustrated in the accompanying drawings herein, can be arranged and designed in various different configurations.

Therefore, the following detailed description of the embodiments of the present disclosure provided in the accompanying drawings is not intended to limit the scope of protection of the present disclosure, but merely represents selected embodiments of the present disclosure. Based on the described embodiments in the present disclosure, all other embodiments obtained by the skilled in the art without creative work belong to the scope of protection of the present disclosure.

It should be noted that similar symbols and letters indicate similar items in the accompanying drawings, therefore, once an item is defined in one drawing, it does not need to be further defined and explained in subsequent drawings.

In the description of the present disclosure, it should also be noted that the terms “arranging”, “installing”, “connecting” and “connection” should be broadly understood. For example, the term “connection” may refer to fixed connection, detachable connection or integrated connection; may refer to direct connection, may refer to indirect connection through an intermediate medium, or may refer to connection inside two elements. For those skilled in the art, the specific meanings of the above terms in the present disclosure can be understood in specific circumstances.

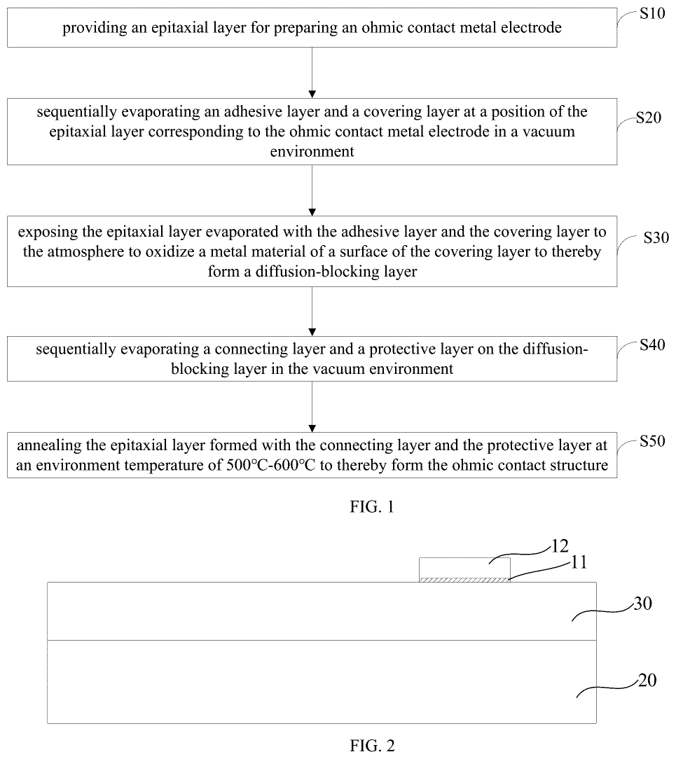

The present disclosure provides a manufacturing method for an ohmic contact structure 10, which includes steps S10 to S50, as illustrated in FIG. 1.

In S10, as illustrated in FIG. 2, an epitaxial layer 30 for manufacturing an ohmic contact metal electrode is provided.

In S20, as illustrated in FIG. 2, in a vacuum environment (e.g., a pressure about 1E-8 pascals (Pa) to 1E-4 Pa), an adhesive layer 11 and a covering layer 12 are sequentially evaporated at a position of the epitaxial layer corresponding to the ohmic contact metal electrode.

In an embodiment, the adhesive layer 11 is made of metal with a lower work function and good adhesion, so that the adhesive layer 11 can be well combined with a semiconductor material of the epitaxial layer 30, thereby improving the yield of the ohmic contact structure in an electrode manufacture process (such as a stripping process). A material of the adhesive layer 11 is not specifically limited in embodiments of the present disclosure, and those skilled in the art can make appropriate selection of the material of the adhesive layer 11 according to the semiconductor material of the epitaxial layer 30. The material of the adhesive layer 11 includes but is not limited to metal such as Ti, Ni, or W.

The covering layer 12 covers the adhesive layer 11 to match with the adhesive layer 11, and a surface of the covering layer 12 facing away from the adhesive layer 11 should be oxidized in an oxygen environment (such as atmosphere environment) in a subsequent step to form a diffusion-blocking layer 13. In the selection of the covering layer 12, metals in the adhesive layer 11 and the covering layer 12 should be mutually dissolved in a subsequent low-temperature annealing process to form a mutually soluble metal compound, and a work function of the mutually soluble metal compound is lower, so as to realize the ohmic contact between the adhesive layer 11 and the covering layer 12 and the epitaxial layer 30. A material of the covering layer 12 depends on the material of the adhesive layer 11, and the material of the covering layer 12 includes but is not limited to metal such as Al or germanium (Ge).

In addition, in an embodiment, as illustrated in FIG. 2, the epitaxial layer 30 is usually disposed on a substrate 20, and the substrate 20 acts as a base to support the epitaxial layer 30.

It should be understood that the ohmic contact structure 10 provided by the embodiments of the present disclosure, as a medium for current conduction, should have a larger conductivity after its manufacturation.

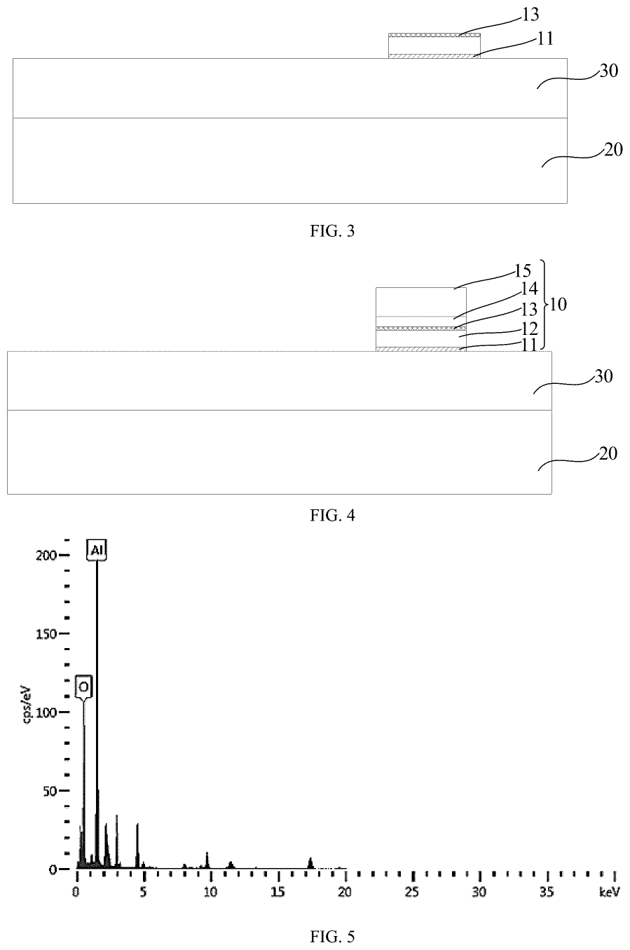

In S30, as illustrated in FIG. 3, the epitaxial layer 30 evaporated with the adhesive layer 11 and the covering layer 12 is exposed to the atmosphere to oxidize a metal material of a surface of the covering layer 12 to thereby form the diffusion-blocking layer 13. A thickness and composition of the diffusion-blocking layer 13 will vary according to an exposure time of the epitaxial layer 30 to the atmosphere.

The diffusion-blocking layer 13 can prevent a connecting layer 14 and a protective layer 15 from diffusing to the adhesive layer 11 and the covering layer 12 during annealing, and can prevent the formed ohmic contact from degenerating into a Schottky contact.

In S40, as illustrated in FIG. 4, the connecting layer 14 and the protective layer 15 are sequentially evaporated on the diffusion-blocking layer 13 in the vacuum environment.

The adhesive layer 11, the covering layer 12, the connecting layer 14 and the protective layer 15 are formed by the evaporation manner, so that during manufacturing the ohmic contact structure, a metal evaporation method can be combined with a photoresist stripping process, which solves the problem that the diffusion-blocking layer 13 is difficult to evaporate. The skilled in the art can set a thickness of each layer according to actual needs, and can thicken the connecting layer 14 and the protective layer 15, thereby avoiding the problems that: owing to the thinner protective layer in the existing low-temperature ohmic process, the thinner protective layer is easy to be etched and perforated in a subsequent process, which reduces the process yield and easily causes device failure.

In S50, the epitaxial layer 30 formed with the connecting layer 14 and the protective layer 15 is annealed at an environment temperature of 500° C.-600° C. to thereby form the ohmic contact structure.

The epitaxial layer 30 formed with the connecting layer 14 and the protective layer 15 is annealed at an environment temperature of 500° C.-600° C., and the environment temperature, i.e., an annealing temperature is lower than a metal melting point of each layer, so that the metal in each layer in the ohmic contact structure 10 can be avoided from melting, and a surface of the ohmic contact structure 10 is smoother.

Specifically, an annealing condition for the epitaxial layer 30 formed with the connecting layer 14 and the protective layer 15 is not limited in the embodiments of the present disclosure. In an embodiment, the epitaxial layer 30 may be annealed at 550° C. for 60 seconds, and an annealing atmosphere for the epitaxial layer 30 formed with the connecting layer 14 and the protective layer 15 is inert gas.

For the manufacturing method for the ohmic contact structure 10 provided by the present disclosure, the annealing process is performed at the environment temperature of 500° C.-600° C., and the annealing temperature is relatively lower, so that the metal in each layer in the ohmic contact structure 10 is prevented from melting, and the surface of the ohmic contact structure 10 is smoother. Further, because the evaporation method is adopted, the photoresist stripping process is not required, so that each layer can be set slightly thicker to form a thicker ohmic contact structure 10. Therefore, the embodiments of the present disclosure can manufacture the ohmic contact structure 10 with a smoother surface and a thicker film layer in a lower temperature environment.

In an embodiment, the epitaxial layer 30 evaporated with the adhesive layer 11 and the covering layer 12 is exposed to the atmosphere for a preset time, to make a thickness of the diffusion-blocking layer 13 be in a range from 1 nanometer (nm) to 10 nm.

The surface of the covering layer 12 is oxidized to form oxide, which is used as the diffusion-blocking layer 13, and the oxide has a compact structure. On the one hand, the diffusion-blocking layer 13 can prevent the connecting layer 14 and the protective layer 15 from diffusing downwards during annealing. Since the protective layer 15 is made of a metal that is not easy to oxidize in the atmosphere, and the metal that is not easy to oxidize has a larger work function, when the metal of the protective layer 15 diffuses downwards and contacts the semiconductor material of the epitaxial layer 30, the formed contact structure is not an ohmic contact structure but a Schottky contact structure, which affects the current transfer of the electrode structure. As such, a thickness of the diffusion-blocking layer 13 should not be too small. On the other hand, the oxide usually have a larger resistivity, when the thickness of the diffusion-blocking layer 13 is smaller, carriers can pass through the diffusion-blocking layer 13 by means of drift diffusion, tunneling, thermionic emission, and the like; when the thickness of the diffusion-blocking layer 13 is too large, carriers will not be able to pass through the diffusion-blocking layer 13, thereby making the resistance of the ohmic contact structure 10 too large, as such, the thickness of the diffusion-blocking layer 13 cannot be too large. Based on the above two reasons, the thickness of the diffusion-blocking layer 13 is set to be between 1 nm and 10 nm in the embodiments of the present disclosure.

In some embodiments, the preset time of the epitaxial layer 30 evaporated with the adhesive layer 11 and the covering layer 12 exposed to the atmosphere is not specifically limited, and those skilled in the art can make specific settings according to an oxidation rate of the covering layer 12 in the atmosphere and an oxygen content in the atmosphere. In an embodiment, the covering layer 12 is made of aluminum metal, and the diffusion-blocking layer 13 is an aluminum oxide layer formed by exposing the aluminum metal in the atmosphere for 10 minutes to 30 minutes, and a thickness of the aluminum layer is 7 nm.

In an embodiment, a process of sequentially evaporating the connecting layer 14 and the protective layer 15 on the diffusion-blocking layer 13 in the vacuum environment includes steps S41 to S43.

In S41, the epitaxial layer 30 formed with the diffusion-blocking layer 13 is placed in a coating chamber of an electron beam evaporation coating machine, and the coating chamber is vacuumized to make a vacuum degree of the coating chamber is below 1.0×10⁻³ pascals (Pa).

In S42, nickel metal is evaporated on the diffusion-blocking layer 13 by using the electron beam evaporation coating machine to form the connecting layer 14.

The connecting layer 14 is made of the nickel metal and thus has good adhesion, therefore, the connecting layer 14 can be well adhered to the diffusion-blocking layer 13.

In S43, a gold material is evaporated on the connecting layer 14 by using the electron beam evaporation coating machine to form the protective layer 15.

Because the adhesive layer 11, the covering layer 12 and the connecting layer 14 are not resistant to a dry etching process, in order to prevent the problem that: the adhesive layer 11, the covering layer 12 and the connecting layer 14 are damaged during a subsequent device process, and thus a resistance of the ohmic contact structure becomes larger, in the embodiment of the present disclosure, the gold material is evaporated on the connecting layer 14 as the protective layer 15. Since the gold material has good corrosion resistance and is not easy to be oxidized in the atmosphere, the protective layer 15 can achieve the purpose of protecting the adhesive layer 11, the covering layer 12 and the connecting layer 14.

In the present disclosure, the diffusion-blocking layer 13 is formed by atmospheric oxidation, and the connecting layer 14 and the protective layer 15 are formed by evaporation on the diffusion-blocking layer 13 by using the electron beam evaporation coating machine, thereby avoiding that a cap layer medium can only be sputtered in the existing low-temperature ohmic technology, thus bypassing the technical problem that the photoresist is difficult to be peeled off after adopting the sputtering method. On the other hand, a production line in the present disclosure does not need sputtering equipment, since the cost of the sputtering equipment is higher, the present disclosure can also save the equipment cost of the production line.

In an embodiment, a process of sequentially evaporating the adhesive layer 11 and a covering layer 12 at the position of the epitaxial layer 30 corresponding to the ohmic contact metal electrode in a vacuum environment includes steps S21 to S23.

In S21, the epitaxial layer 30 is placed in a coating chamber of an electron beam evaporation coating machine, and the coating chamber is vacuumized to make a vacuum degree of the coating chamber be below 1.0×10⁻³ Pa;

In S22, titanium metal is evaporated at the position of the epitaxial layer 30 corresponding to the ohmic contact metal electrode by using the electron beam evaporation coating machine to form the adhesive layer 11.

In S23, aluminum metal is evaporated on the adhesive layer 11 by using the electron beam evaporation coating machine to form the covering layer 12.

When the ohmic contact structure 10 is applied to a gallium nitride-based HEMT device, since the adhesive layer 11 is made of the titanium metal, after the epitaxial layer 30 formed with the connecting layer 14 and the protective layer 15 is annealed, the titanium metal of the adhesive layer 11 and the aluminum metal of the covering layer form a TiAlx compound, which has a lower work function and is easier to form ohmic contact with nitride of the epitaxial layer 30. In the subsequent annealing process, the titanium metal reacts with a gallium nitride system to extract nitrogen from the gallium nitride system, and the reaction produces titanium nitride, which makes the gallium nitride system re-form nitrogen vacancies, and the nitrogen vacancies make N-type doping in the gallium nitride system, which is also conducive to the formation of good ohmic metal and reduces the resistance of the ohmic contact structure 10.

In an embodiment, the covering layer 12 is made of aluminum metal, and a process of exposing the epitaxial layer 30 evaporated with the adhesive layer 11 and the covering layer 12 to the atmosphere to oxidize the metal material of the surface of the covering layer to thereby form the diffusion-blocking layer 13 includes: exposing the aluminum metal of a surface of the covering layer 12 the atmosphere, to make the aluminum metal react with oxygen in the atmosphere to generate an aluminum oxide layer as the diffusion-blocking layer 13.

The aluminum metal is easily oxidized in the atmosphere, a dense aluminum oxide layer is formed after oxidation, and a surface of the aluminum oxide layer is dense. On the one hand, the aluminum oxide layer can prevent the aluminum metal from being oxidized continuously, and on the other hand, the aluminum oxide layer can prevent the connecting layer 14 and the protective layer 15 from diffusing to the aluminum metal layer during annealing.

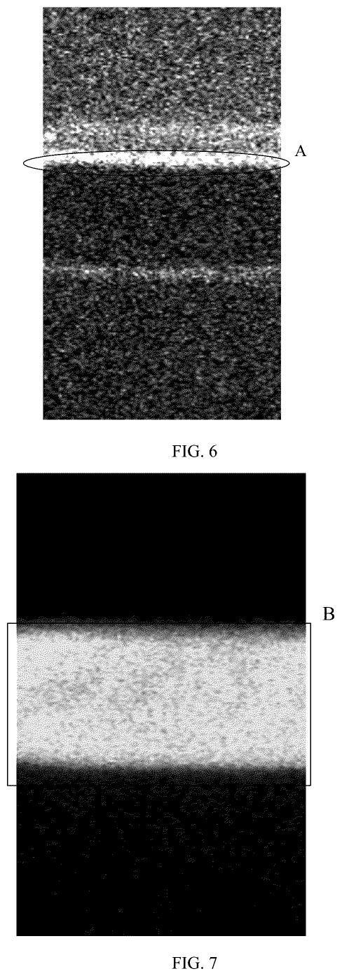

In an embodiment, a number ratio of an aluminum atom to an oxygen atom in the aluminum oxide layer is not limited. FIG. 5 illustrates an energy dispersive spectroscopy (EDS) single-point scanning diagram of the diffusion-blocking layer 13 according to an embodiment of the present disclosure. According to the scanning diagram, the aluminum atom accounts for 49.7%, the oxygen atom accounts for 50.3%, and the number ratio of the aluminum atom and the oxygen atom in the aluminum oxide layer is about 1:1. FIG. 6 and FIG. 7 illustrate EDS mappings of a diffusion-blocking layer 13 according to an embodiment of the present disclosure, which respectively reveal the distribution of the oxygen atom and the aluminum atom in the ohmic contact structure 10, with the oxygen atom at a position Ain FIG. 6 and the aluminum atom at a position B in FIG. 7.

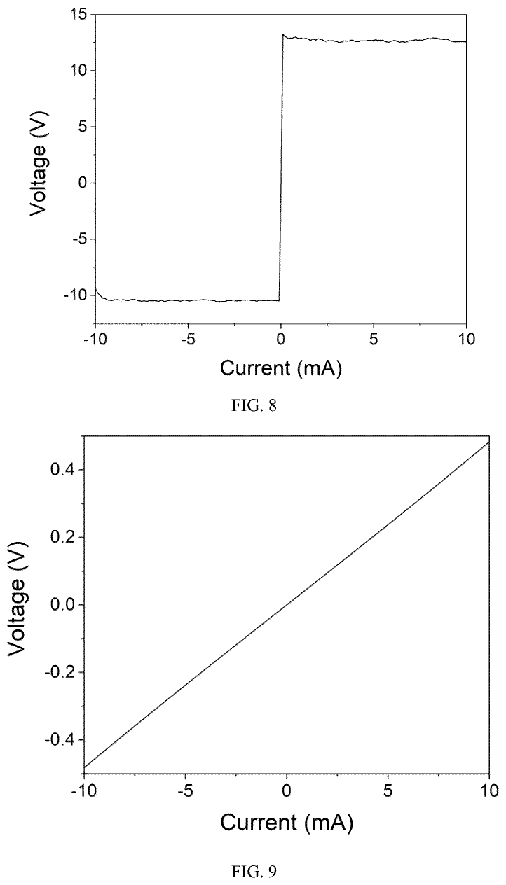

In addition, in order to further verify the performance of the ohmic contact structure 10 provided by the embodiments of the application in a gallium nitride-based HEMT device, a voltage-current relationship of a Ti/Al/Ni/Au structure manufactured by the existing low-temperature ohmic technology and a voltage-current relationship of the ohmic contact structure 10 of Ti/Al/AlOx/Ni/Au provided by the embodiments of the application are compared and tested. Both the structures are annealed at 550° C. for 60 seconds, and the epitaxies of the two structures are both nitride HEMT epitaxial layer. As can be seen from FIG. 8, the Ti/Al/Ni/Au structure in the related art forms a Schottky contact after low-temperature annealing, which shows that the gold material of the protective layer 15 diffuses to the position of the Schottky contact. As can be seen from FIG. 9, the ohmic contact structure 10 of Ti/Al/AlOx/Ni/Au provided by the embodiments of the present disclosure is still ohmic contact after annealing, so the AlOx layer as the diffusion-blocking layer 13 in the embodiments of the present disclosure can prevent the diffusion of the gold material and the nickel metal, thereby achieving the purpose of the present disclosure. In the embodiments of the present disclosure, the ohmic contact structure 10 is formed by two-stage evaporation, and the aluminum oxide layer is formed by natural oxidation of the aluminum layer in the atmosphere, which has a compact structure and can block the annealing diffusion of the nickel and gold layers.

The present disclosure is applied to a gallium nitride (GaN)-based HEMT device, and an epitaxial layer 30 for manufacturing an ohmic contact metal electrode is provided. The epitaxial layer includes a heterojunction composed of a channel layer and a diffusion-blocking layer. The diffusion-blocking layer may be aluminum nitride, aluminum indium nitride, aluminum gallium nitride, indium gallium nitride or aluminum indium gallium nitride.

Moreover, an embodiment of the present disclosure provides an ohmic contact structure 10. As shown in FIG. 4, the ohmic contact structure 10 is a source electrode and/or a drain electrode of a HEMT device. The ohmic contact structure includes an adhesive layer 11, a covering layer 12, a diffusion-blocking layer 13, a connecting layer 14, and a protective layer 15 which are sequentially arranged on an epitaxial layer 30 in that order, and the diffusion-blocking layer 13 is an oxide of a metal material of the covering layer 12.

The ohmic contact structure 10 provided by the embodiment of the present disclosure is manufactured by the above-mentioned manufacturing method of the ohmic contact structure 10, the diffusion-blocking layer 13 is an oxide of the metal material of the covering layer 12 and has a relatively compact structure, which can prevent the connecting layer 14 and the protective layer 15 from diffusing to the position where the metal material contacts with the semiconductor material of the epitaxial layer 30 during annealing, and thus a good ohmic contact is formed.

In an embodiment, a thickness of each of the adhesive layer 11, the covering layer 12, the connecting layer 14 and the protective layer 15 can be set according to actual needs, thus avoiding the problem that the thinner ohmic contact structure 10 is easily etched and perforated in a subsequent process, thereby reducing the process yield and prone to device failure.

In an embodiment, the adhesive layer 11 includes a titanium layer with a thickness in a range from 10 Å to 200 Å, the covering layer 12 includes an aluminum layer with a thickness in a range from 50 Å to 2000 Å, the diffusion-blocking layer 13 is an aluminum oxide layer with a thickness in a range from 10 Å to 100 Å, the connecting layer 14 includes a nickel layer with a thickness in a range from 100 Å to 500 Å, and the protective layer 15 includes a gold layer with a thickness in a range from 500 Å to 2000 Å.

When the ohmic contact structure 10 is applied to the GaN-based HEMT device, the adhesive layer 11 is a titanium layer made of titanium metal, and the covering layer 12 is formed by evaporating aluminum metal on the titanium layer. Because the titanium aluminum compound has a lower work function and is easy to form ohmic contact with nitride, and in the subsequent annealing process, the titanium metal reacts with the gallium nitride system to extract nitrogen from the gallium nitride system, and the reaction produces titanium nitride, which makes the gallium nitride system re-form nitrogen vacancies, and the nitrogen vacancies make the N-type doping in the gallium nitride system, which is also conducive to the formation of good ohmic metal and reduces the resistance of the ohmic contact structure 10. After annealing, the adhesive layer 11 and the covering layer 12 finally each become a titanium-aluminum compound. Elements of the adhesive layer 11 include titanium and aluminum, and elements of the covering layer 12 also include titanium and aluminum, a titanium content of the adhesive layer 11 is higher than that of the covering layer 12, and an aluminum content of the covering layer 12 is higher than that of the adhesive layer 11.

The diffusion-blocking layer 13 is formed by oxidation of the covering layer 12 in the atmosphere. When the covering layer 12 is an aluminum layer, the diffusion-blocking layer 13 is an aluminum oxide layer, and a surface of the aluminum oxide layer is compact. On the one hand, the aluminum oxide layer can prevent the aluminum metal from being continuously oxidized; on the other hand, the aluminum oxide layer can also prevent the connecting layer 14 and the protective layer 15 from diffusing to the covering layer 12 during annealing.

The connecting layer 14 is made of nickel metal, which has a compact structure and can prevent the downward diffusion of gold material. In other embodiments, the connecting layer can also be made of a material such as Ti, TiN, Cu, or W.

The protective layer 15 is made of a gold material, which has good corrosion resistance and is not easy to be oxidized in the atmosphere, thereby protecting the adhesive layer 11, the covering layer 12, and the connecting layer 14.

In an embodiment, the protective layer 15 is made of gold metal, and the connecting layer 14 is made of nickel metal, after annealing, a nickel-gold compound is formed, elements of the connecting layer 14 include nickel and gold, and elements of the protective layer 15 include gold and nickel, a nickel content of the connecting layer 14 is higher than that of the protective layer 15, and a gold content of the protective layer 15 is higher than that of the connecting layer 14.

In an embodiment, a thickness ratio of the adhesive layer 11 to the covering layer 12 is in a range from 1:50 to 1:5.

The adhesive layer 11 and the covering layer 12 react in solid state to form a metal compound with a lower work function. Based on the function of the adhesive layer 11 and the covering layer 12, a thickness ratio of the adhesive layer 11 to the covering layer 12 is in a range from 1:50 to 1:5.

An embodiment of the present disclosure also discloses an HEMT device, which includes: a substrate 20, an epitaxial layer 30 disposed on the substrate 20, and a source electrode and a drain electrode disposed on the epitaxial layer 30 at intervals. Each of the source electrode and the drain electrode is an ohmic contact structure 10. The ohmic contact structure 10 adopts the above-mentioned ohmic contact structure, and the HEMT device includes the same structure and beneficial effects as the ohmic contact structure 10 in the previous embodiments. The structure and beneficial effects of the ohmic contact structure 10 have been described in detail in the previous embodiments, and will not be repeated herein.

The present disclosure also provides a power amplification module applying the HEMT device. The power amplification module includes the HEMT device and other electronic components. The present disclosure also provides a power switch module applying the HEMT device. The power switch module includes the HEMT device and other electronic components.

The above is merely exemplary embodiments of the present disclosure, and it is not used to limit the present disclosure. For those skilled in the art, the present disclosure can be modified and varied. Any modification, equivalent substitution, and improvement made within the spirit and principles of the present disclosure shall be included in the scope of protection of the present disclosure.

What is claimed is:

1. A high electron mobility transistor (HEMT) device, comprising:
an epitaxial layer;
an adhesive layer, disposed on the epitaxial layer;
a covering layer, disposed on a side of the adhesive layer facing away from the epitaxial layer;
a diffusion-blocking layer, disposed on a side of the covering layer facing away from the adhesive layer;
a connecting layer, disposed on a side of the diffusion-blocking facing away from the covering layer; and
a protective layer, disposed on a side of the connecting layer facing away from the diffusion-blocking layer, wherein the diffusion-blocking layer is an oxide of a metal material of the covering layer.

2. The HEMT device according to claim 1, wherein the diffusion-blocking layer is an aluminum oxide layer.

3. The HEMT device according to claim 1, wherein the protective layer comprises gold metal (Au).

4. The HEMT device according to claim 1, wherein the connecting layer comprises at least one selected from the group consisting of nickel (Ni), tungsten (W), titanium (Ti), titanium nitride (TiN), and copper (Cu).

5. The HEMT device according to claim 1, wherein the adhesive layer and the covering layer are titanium-aluminum compounds, elements of each of the adhesive layer and the covering layer are titanium and aluminum, a titanium content of the adhesive layer is higher than that of the covering layer, and an aluminum content of the covering layer is higher than that of the adhesive layer.

6. The HEMT device according to claim 1, wherein a thickness of the adhesive layer is in a range from 10 angstroms (Å) to 200 Å, and a thickness of the covering layer is in a range from 50 Å to 2000 Å.

7. The HEMT device according to claim 1, wherein a thickness of the diffusion-blocking layer is in a range from 10 Å to 100 Å.

8. The HEMT device according to claim 1, wherein a thickness of the connecting layer is in a range from 100 Å to 500 Å, and a thickness of the protective layer is in a range from 500 Å to 2000 Å.

9. The HEMT device according to claim 1, wherein a thickness ratio of the adhesive layer to the covering layer is in a range from 1:50 to 1:5.

10. A power amplification module, comprising the HEMT device according to claim 1.

11. A power switch module, comprising the HEMT device according to claim 1.

12. An ohmic contact structure, comprising:
an adhesive layer;
a covering layer, disposed on a side of the adhesive layer;
a diffusion-blocking layer, disposed on a side of the covering layer facing away from the adhesive layer;
a connecting layer, disposed on a side of the diffusion-blocking layer facing away from the covering layer, and
a protective layer, disposed on a side of the connecting layer facing away from the diffusion-blocking layer, wherein the diffusion-blocking layer is an oxide of a metal material of the covering layer.

13. The ohmic contact structure of claim 12, wherein the diffusion-blocking layer is an aluminum oxide layer, and the protective layer comprises gold metal.

14. The ohmic contact structure according to claim 12, wherein a thickness of the adhesive layer is in a range from 10 Å to 200 Å, a thickness of the covering layer is in a range from 50 Å to 2000 Å, a thickness of the diffusion-blocking layer is in a range from 10 Å to 100 Å, a thickness of the connecting layer is in a range from 100 Å to 500 Å, and a thickness of the protective layer is in a range from 500 Å to 2000 Å.

15. The ohmic contact structure according to claim 12, wherein a thickness ratio of the adhesive layer to the covering layer is in a range from 1:50 to 1:5.

16. A manufacturing method for an HEMT device, comprising:
sequentially forming an adhesive layer and a covering layer on an epitaxial layer;
forming a diffusion-blocking layer on the covering layer; and
sequentially forming a connecting layer and a protective layer on the diffusion-blocking layer;
wherein the diffusion-blocking layer is an oxide of a metal material of the covering layer.

17. The manufacturing method for an HEMT device according to claim 16,
wherein the sequentially forming an adhesive layer and a covering layer on an epitaxial layer comprises: sequentially evaporating the adhesive layer and the covering layer at a position of the epitaxial layer corresponding to an electrode in a vacuum environment;
wherein the forming a diffusion-blocking layer on the covering layer comprises: exposing the epitaxial layer evaporated with the adhesive layer and the covering layer to the atmosphere to oxidize the metal material of a surface of the covering layer to form the diffusion-blocking layer; and exposing the epitaxial layer evaporated with the adhesive layer and the covering layer to the atmosphere for a preset time to make a thickness of the diffusion-blocking layer be in a range from 1 nanometer (nm) to 10 nm; and
wherein the sequentially forming a connecting layer and a protective layer on the diffusion-blocking layer to thereby form the ohmic contact structure comprises: sequentially evaporating the connecting layer and the protective layer on the diffusion-blocking layer in the vacuum environment; and annealing the epitaxial layer formed with the connecting layer and the protective layer at an environment temperature of 500° C.-600° C. to thereby form the ohmic contact structure.

18. The manufacturing method for an HEMT device according to claim 17, wherein the sequentially evaporating the connecting layer and the protective layer on the diffusion-blocking layer in the vacuum environment comprises:
placing the epitaxial layer formed with the diffusion-blocking layer in a coating chamber of an electron beam evaporation coating machine, and vacuumizing the coating chamber;
evaporating nickel metal on the diffusion-blocking layer to form the connecting layer; and
evaporating a gold material on the connecting layer to form the protective layer.

19. The manufacturing method for an HEMT device according to claim 17, wherein the sequentially evaporating the adhesive layer and the covering layer at a position of the epitaxial layer corresponding to an electrode in a vacuum environment comprises:
placing the epitaxial layer in a coating chamber of an electron beam evaporation coating machine and vacuumizing the coating chamber;
evaporating titanium metal at the position of the epitaxial layer corresponding to the ohmic contact metal electrode to form the adhesive layer; and
evaporating aluminum metal at the position of the epitaxial layer corresponding to the electrode to form the covering layer, wherein the covering layer covers the adhesive layer.

20. The manufacturing method for an HEMT device according to claim 17, wherein the covering layer is made of aluminum metal;
wherein the exposing the epitaxial layer evaporated with the adhesive layer and the covering layer to the atmosphere to oxidize the metal material of a surface of the covering layer to form the diffusion-blocking layer comprises: exposing the aluminum metal of the surface of the covering layer to the atmosphere, to make the aluminum metal react with oxygen in the atmosphere to form an aluminum oxide layer as the diffusion-blocking layer.
